(19) United States
(12) Patent Application Publication
(10) Pub. No.: US 2025/0316498 A1
(43) Pub. Date: Oct. 9, 2025

(54) WIRING STRUCTURE MANUFACTURING METHOD AND THE WIRING STRUCTURE

(71) Applicant: Samsung Electronics Co., Ltd., Suwon-si (KR)

(72) Inventors: TAEHWA JEONG, Suwon-si (KR); HYOJIN YUN, Suwon-si (KR); UN-BYOUNG KANG, Suwon-si (KR); Taehee KIM, Suwon-si (KR)

(21) Appl. No.: 18/966,896

(22) Filed: Dec. 3, 2024

(30) Foreign Application Priority Data
Apr. 8, 2024 (KR) 10-2024-0047592

(51) Int. Cl. H01L 21/48; H01L 23/498; H05K 1/11

(52) U.S. Cl. CPC H01L 21/4857; H01L 21/486; H01L 23/49822; H05K 1/115

(57) ABSTRACT

A method for manufacturing a wire structure includes: forming a first conductive pattern on a substrate; forming a protection pattern on the first conductive pattern; forming a photosensitive insulating layer for covering the first conductive pattern and the protection pattern; patterning the photosensitive insulating layer by an exposure process and a development process, removing at least a portion of the protection pattern, and forming a via hole in the photosensitive insulating layer and the protection pattern, the via hole exposing at least a portion of the first conductive pattern; forming a via filling at least a portion of the via hole and connected to the first conductive pattern; and forming a second conductive pattern connected to the via on the via.

### CROSS-REFERENCE TO RELATED APPLICATION

This application claims priority to and the benefit of Korean Patent Application No. 10-2024-0047592 filed in the Korean Intellectual Property Office on Apr. 8, 2024, the entire contents of which are incorporated herein by reference.

### BACKGROUND OF THE INVENTION

### (a) Field of the Invention

The present disclosure relates to a wire structure manufacturing method and a wire structure.

### (b) Description of the Related Art

In response to the demand for high density and high performance integrated circuits (ICs), technology to form photo vias on photosensitive insulating materials such as PID (Photo Imageable Dielectric) by exposure and development processes is being used. For example, the photo vias may be formed by coating a photosensitive insulating material, disposing a photomask on the photosensitive insulating material, irradiating light, removing the exposed region with a developer to form a via hole, and filling the inside of the via hole with a metal material.

### SUMMARY OF THE INVENTION

The present disclosure attempts to prevent generation of residues of a photosensitive insulating layer on a wire pattern, and generation of electrical connection defects of the wire pattern.

According to an embodiment of the present disclosure, a method for manufacturing a wire structure includes: forming a first conductive pattern on a substrate; forming a protection pattern on the first conductive pattern; forming a photosensitive insulating layer for covering the first conductive pattern and the protection pattern; patterning the photosensitive insulating layer by an exposure process and a development process, removing at least a portion of the protection pattern, and forming a via hole in the photosensitive layer and the protection pattern, the via hole exposing at least a portion of the first conductive pattern; forming a via filling at least a portion of the via hole and connected to the first conductive pattern; and forming a second conductive pattern connected to the via on the via.

According to another embodiment of the present disclosure, a method for manufacturing a wire structure includes: forming a first conductive pattern on a substrate; forming a passivation layer for covering the first conductive pattern; forming a photosensitive insulating layer for covering the passivation layer; patterning the photosensitive insulating layer by an exposure process and a development process, removing a portion of the passivation layer, and forming a via hole in the photosensitive layer and the passivation layer, the via hole exposing at least a portion of the first conductive pattern; forming a via filling at least a portion of the via hole and connected to the first conductive pattern; and forming a second conductive pattern connected to the via on the via.

According to another embodiment of the present disclosure, a wire structure includes: a first conductive pattern; a passivation layer for covering the first conductive pattern; a photosensitive insulating layer for covering the passivation layer; a via penetrating the passivation layer and the photosensitive insulating layer, the via being connected to the first conductive pattern; and a second conductive pattern disposed on the via and connected to the via.

According to the present disclosure, the formation of residues of the photosensitive insulating layer on the wire pattern, and the resultant generation of electrical connection defects of the wire pattern may be prevented.

### BRIEF DESCRIPTION OF THE DRAWINGS

FIG. 1 to FIG. 6 show a method for manufacturing a wire structure according to a comparative example.

FIG. 7 shows a structure in which residues of a photosensitive insulating layer are formed on a wire pattern.

FIG. 8 to FIG. 16 show a method for manufacturing a wire structure according to an embodiment.

FIG. 17 to FIG. 23 show a method for manufacturing a wire structure according to an embodiment.

FIG. 24 shows a cross-sectional view of a semiconductor package including a wire structure according to an embodiment.

FIG. 25 shows a cross-sectional view of a semiconductor package including a wire structure formed according to an embodiment.

FIG. 26 shows a cross-sectional view of a semiconductor package including a wire structure formed according to an embodiment.

FIG. 27 shows a cross-sectional view of a semiconductor package including a wire structure formed according to an embodiment.

### DETAILED DESCRIPTION OF THE EMBODIMENTS

In the following detailed description, only certain embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

Throughout this specification and the claims that follow, when it is described that an element is “coupled” to another element, the element may be “directly coupled” to the other element or “indirectly coupled” to the other element through a third element. In a similar sense, this includes being “physically connected” as well as being “electrically connected”.

It will be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

The phrase “in a plan view” means viewing an object portion from the top, and the phrase “in a cross-sectional view” means viewing a cross-section of which the object portion is vertically cut from the side.

Throughout the specification, sequential numbers such as first and second are used to distinguish a constituent element from other constituent elements that are the same or similar to it, and are not necessarily intended to refer to a specific constituent element. Accordingly, a component referred to as the first constituent element in one part of this specification may be referred to as a second constituent element in another part of this specification.

References to any constituent element in the singular form include references to a plurality of those constituent elements, unless specifically stated to the contrary.

A comparative example and an embodiment according to the present disclosure will now be described with reference to drawings.

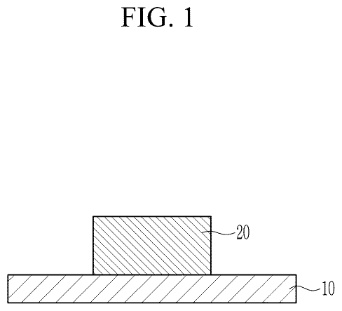

FIG. 1 to FIG. 6 show a method for manufacturing a wire structure according to a comparative example.

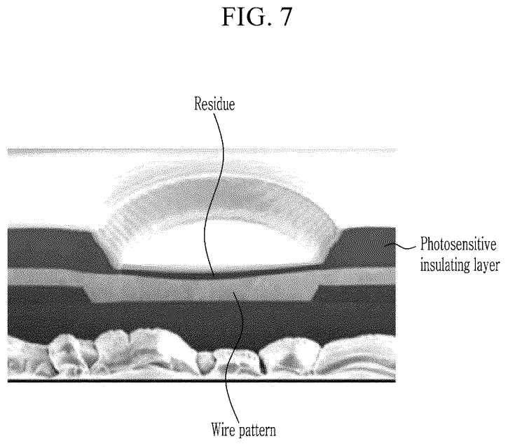

FIG. 7 shows a structure in which residues of a photosensitive insulating layer are formed on a wire pattern of a wire structure formed according to a comparative example.

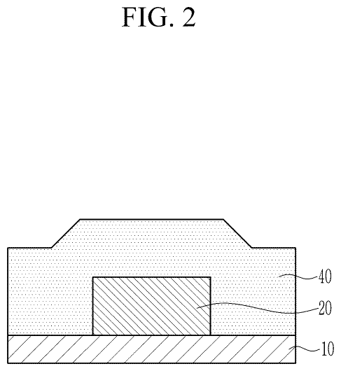

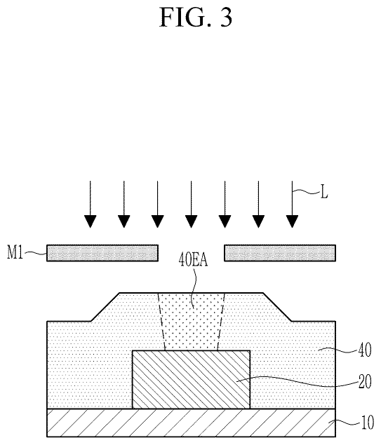

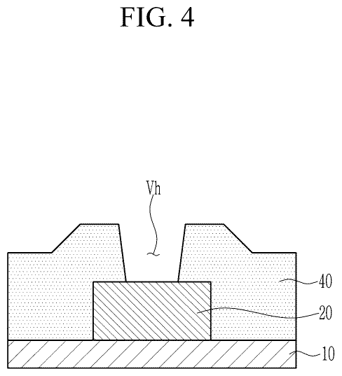

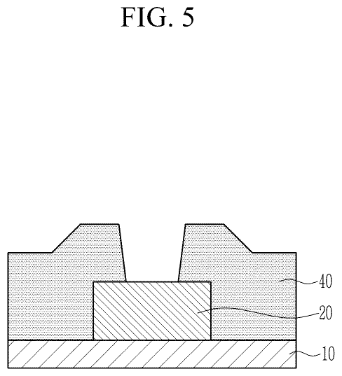

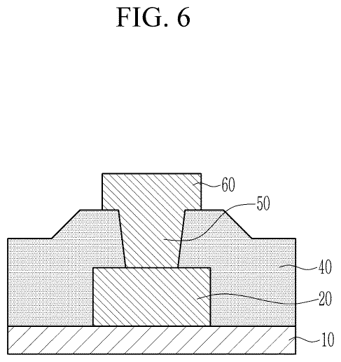

Referring to the drawings, the method for manufacturing a wire structure according to a comparative example may include: forming a first conductive pattern 20 on a substrate 10 (see FIG. 1), forming a photosensitive insulating layer 40 for covering a first conductive pattern 20 (see FIG. 2), patterning the photosensitive insulating layer 40 by an exposure process and a development process to form a via hole Vh (see FIG. 3 and FIG. 4), curing the photosensitive insulating layer 40 (see FIG. 5), and forming a via 50 and a second conductive pattern 60 (see FIG. 6).

When the photosensitive insulating layer 40 is exposed, the residues of the photosensitive insulating layer 40 may be formed on the first conductive pattern 20 because of a reaction between the photosensitive insulating layer 40 and the first conductive pattern 20 by the light L. For example, SO₂ that is a thermally decomposed product of a photo acid compound (PAD) from among the components of the photosensitive insulating layer 40 may react to copper (Cu) of the conductive pattern to form a compound of CuₓS_{y}. In another way, room-temperature reaction materials of ions (H₃O⁺, HSO₃_{^{−}}, SO₃_{^{−}}, SO₄²⁻, OH⁻, etc.,) formed after SO₂ is dissolved in moisture may be formed because of the presence of moisture (H₂O). The residues have insulating properties, and if they remain on the first conductive pattern 20, they may cause an electrical connection failure between the via 50 and the first conductive pattern 20.

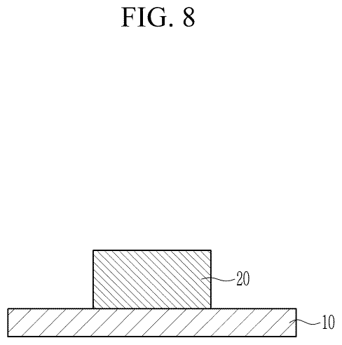

FIG. 8 to FIG. 16 show a method for manufacturing a wire structure according to an embodiment.

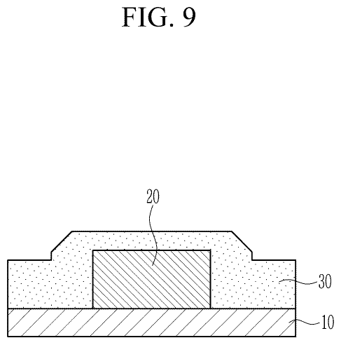

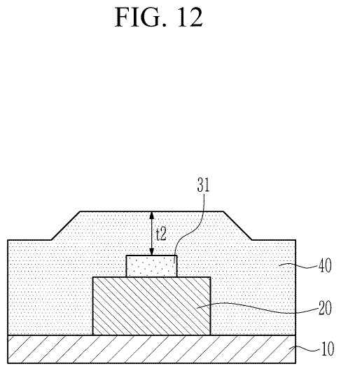

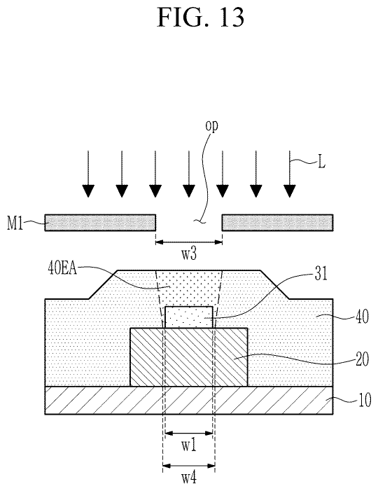

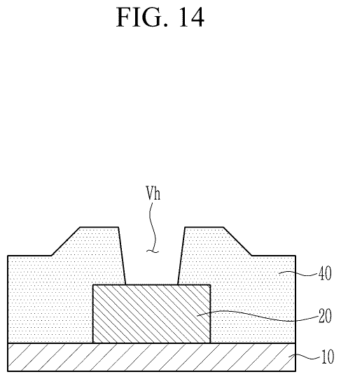

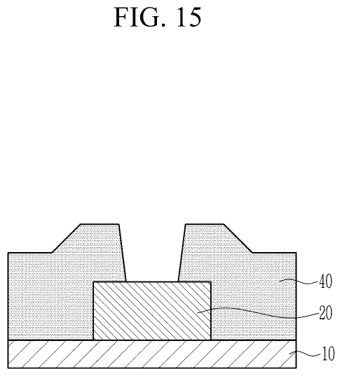

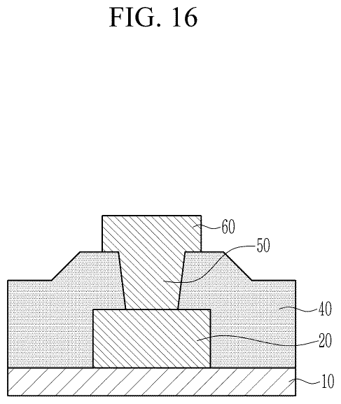

A method for manufacturing a wire structure according to an embodiment may include: forming a first conductive pattern 20 on the substrate 10 (see FIG. 8), forming a protection pattern 31 on the first conductive pattern 20 (see FIGS. 9 to 11), forming a photosensitive insulating layer 40 for covering the first conductive pattern 20 and the protection pattern 31 (see FIG. 12), patterning the photosensitive insulating layer 40 by an exposure process and a development process (see FIG. 13), removing at least a portion of the protection pattern 31 to form a via hole Vh exposing at least a portion of the first conductive pattern 20 (see FIG. 14), curing the photosensitive insulating layer 40 (see FIG. 15), forming a via 50 filling at least a portion of the via hole Vh and connected to the first conductive pattern 20 (see FIG. 16), and forming a second conductive pattern 60 connected to the via 50 (see FIG. 16).

Referring to FIG. 8, a first conductive pattern 20 may be formed on the substrate 10. The substrate 10 may not be limited to a specific type, and the substrate 10 may be a portion of the substrate or a semiconductor chip.

The first conductive pattern 20 may be a wire pattern (e.g., signal pattern, power pattern, or ground pattern) of the substrate, or a connection pad of the semiconductor chip. The first conductive pattern 20 may include a pad region overlapping the via 50 to be connected to the same in a plan view.

The first conductive pattern 20 may be made of a conductive material, it may be formed of, for example, copper (Cu), aluminum (Al), silver (Ag), gold (Au), platinum (Pt), nickel (Ni), titanium (Ti), palladium (Pd), and alloys thereof. The first conductive pattern 20 may have layers. For example, the first conductive pattern 20 may be generated by forming a seed layer on the substrate 10 and a plating layer on the seed layer.

Only a single first conductive pattern 20 is shown in the drawing, but multiple first conductive patterns 20 may also be formed.

Referring to FIG. 9 to FIG. 11, a protection pattern 31 may be formed on the first conductive pattern 20.

The protection pattern 31 may include photoresist (e.g., a photoresist material), and may be formed through a photo process. For example, the forming of a protection pattern 31 may include forming a photoresist layer 30 for covering the first conductive pattern 20 and patterning the photoresist layer 30 by an exposure process and a development process (e.g., a second exposure process and a second development process).

Referring to FIG. 9, a photoresist layer 30 may be formed to cover the first conductive pattern 20. When the photoresist layer 30 is formed, the photoresist layer 30 may cover the substrate 10 together with the first conductive pattern 20. The photoresist layer 30 may be formed by a spin coating or a spray coating.

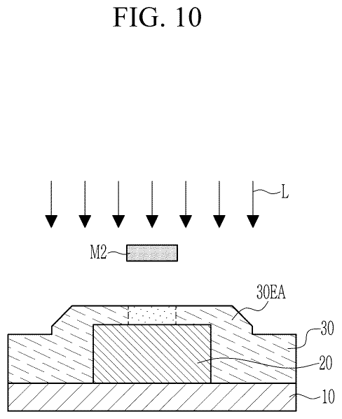

Referring to FIG. 10, a photomask M2 may be arranged on the photoresist layer 30, and light L may be irradiated to the photoresist layer 30 through the photomask M2 to thus perform an exposure process. The photoresist layer 30 may be formed of a positive type material in which the region that is irradiated by light is thereafter removed by the development process. Therefore, the photomask M2 may be arranged in a region in which a protection pattern 31 will be formed such that the photomask M2 prevents the light L from being irradiated to the region in which the protection pattern 31 will be formed.

The light L used during the exposure process may, for example, be ultraviolet rays with a wavelength of about 365 nm.

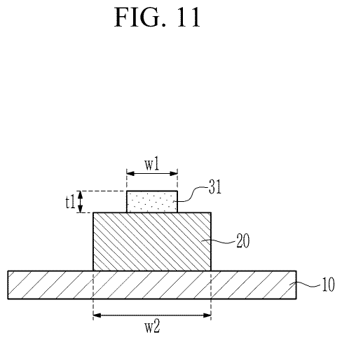

Referring to FIG. 11, a protection pattern 31 may be formed on the first conductive pattern 20 by performing the development process for rinsing the photoresist layer 30 with a developer and removing the exposure region 30EA.

The protection pattern 31 may be formed to have a smaller thickness than the photosensitive insulating layer 40. For example, the thickness t1 (see FIG. 11) of the protection pattern 31 may be less than the thickness t2 (see FIG. 12) of the portion of the photosensitive insulating layer 40 that is on the protection pattern 31. To be described later, the protection pattern 31 may be removed in a subsequent process, and it may be preferable for the protection pattern 31 to be thin for an efficient removal of the protection pattern 31.

Additionally, the protection pattern 31 may be formed to have a smaller width than the first conductive pattern 20 in a cross-sectional view, and the protection pattern 31 may be disposed only on some regions of the first conductive pattern 20. In other words, the width w1 of the protection pattern 31 formed during the manufacturing process may be less than the width w2 of the first conductive pattern 20. For example, the width in a cross-sectional view of the protection pattern 31 may be similar to the width of the via hole Vh to be formed. Preferably, for a complete removal of the protection pattern 31 in the process for forming the via hole Vh, the width w1 of the protection pattern 31 may be equal to or less than the width w4 (see FIG. 13) of the via hole Vh at its bottom. When removing the protection pattern 31, the region of the photosensitive layer that covers the sides of protection pattern 31 may also be removed.

Referring to FIG. 12, a photosensitive insulating layer 40 for covering the first conductive pattern 20 and the protection pattern 31 may be formed. The photosensitive insulating layer 40 may be a photo imageable dielectric (PID). When the photosensitive insulating layer 40 is used, the photo vias may be formed, making it easy to implement fine pitches. The photosensitive insulating layer 40 may be formed through a lamination process, but is not limited thereto.

Referring to FIG. 13 and FIG. 14, the photosensitive insulating layer 40 may be patterned through the exposure process and the development process, and at least a portion of the protection pattern 31 may be removed to form a via hole Vh for exposing at least a portion of the first conductive pattern 20.

Referring to FIG. 13, the photomask M1 may be arranged on the photosensitive insulating layer 40, and the exposure process for irradiating light L on the photosensitive insulating layer 40 through photomask M1 may be performed. The photosensitive insulating layer 40 may be formed of a positive type material in which the region that is irradiated by light is thereafter removed by the development process. Therefore, the photomask M1 may have an open region op disposed in the region where the via hole Vh will be formed, and the light L may be irradiated to the region where the via hole Vh will be formed.

Referring to FIG. 14, the development process for rinsing the photosensitive insulating layer 40 with a developer to remove the exposure region 40EA (see FIG. 13) may be performed, and the protection pattern 31 may be removed to form the via hole Vh.

As described above, when the protection pattern 31 includes a photoresist, the protection pattern 31 may be removed along with a portion of the photosensitive insulating layer 40 by the exposure process and the development process of the photosensitive insulating layer 40. For example, the protection pattern 31 may also be exposed through the open region op of the photomask M1 during the process for exposing the photosensitive insulating layer 40, and the protection pattern 31 may also be developed and may be removed during the development process. By removing the photosensitive insulating layer 40 and the protection pattern 31 through the same exposure and development process, the process time and cost may be shortened.

At this time, the photosensitivity of the protection pattern 31 may be greater than the photosensitivity of the photosensitive insulating layer 40. That is, the protection pattern 31 may react to light L in a shorter time than the photosensitive insulating layer 40. The protection pattern 31 may absorb the light transmitted through the photosensitive insulating layer 40 so it may be preferable to have a photosensitivity greater than that of the photosensitive insulating layer 40 for the efficient exposure process.

However, if necessary, the protection pattern 31 may be removed separately from the photosensitive insulating layer 40. For example, the photosensitive insulating layer 40 may be patterned by the exposure process and the development process, and the protection pattern 31 may be removed separately to form a via hole Vh. In this embodiment, the method for removing the protection pattern 31 may not be particularly limited, and the protection pattern 31 may be removed according to a separate exposure process and development process, or may be removed by a chemical method such as etching, a mechanical method, etc., depending on the material.

The entire protection pattern 31 may be removed when the via hole Vh is formed. It may be desirable to remove the entire protection pattern 31 to prevent the protection pattern 31 from affecting the product by being denatured under conditions such as temperatures or pressures of the subsequent process. For example, when via hole Vh is formed and the protection pattern 31 remains, this may cause the protection pattern 31 to be denatured at the curing temperature, input or diffused to the first conductive pattern 20, and pollute the first conductive pattern 20 in a subsequent process for curing the photosensitive insulating layer 40, which may be undesirable.

To remove the entire protection pattern 31 by the exposure and development process, the entire region of the protection pattern 31 may overlap the open region op of the photomask M1 in a plan view. For example, the width w3 of the open region op of the photomask M1 may be equal to or greater than the width w1 of the protection pattern 31 in a cross-sectional view. An area of the open region op of the photomask M1 may be greater than the area of the protection pattern 31 when viewed in plan view.

However, the protection pattern 31 may not be completely removed and may remain in the wire structure, depending on the material of the protection pattern 31. When the protection pattern 31 remains in the wire structure, the protection pattern 31 may be covered with the photosensitive insulating layer 40 and may be exposed as a sidewall that is adjacent to a bottom of the via hole Vh.

Reactivity of the first conductive pattern 20 and the protection pattern 31 may be lower than the reactivity of the first conductive pattern 20 and the photosensitive insulating layer 40. The first conductive pattern 20 and the protection pattern 31 may not react with each other. When the light L is irradiated, the first conductive pattern 20 and the protection pattern 31 may not react with each other. Therefore, the residues of the protection pattern 31 may not remain on the first conductive pattern 20 when the development process is performed.

Referring to FIG. 15, the method for manufacturing a wire structure may further include curing the photosensitive insulating layer 40. The shape of the via hole Vh of the photosensitive insulating layer 40 may be maintained by curing the photosensitive insulating layer 40. Curing of the photosensitive insulating layer 40 may be performed at a specific temperature for a specific time.

Referring to FIG. 16, a via 50 filling at least a portion of the via hole Vh and connected to the first conductive pattern 20 may be formed, and a second conductive pattern 60 connected to the via 50 may be formed on the via 50.

The via 50 and the second conductive pattern 60 may be formed of conductive materials, for example, copper (Cu), aluminum (Al), silver (Ag), gold (Au), platinum (Pt), nickel (Ni), titanium (Ti), palladium (Pd), or their alloys. The via 50 and the second conductive pattern 60 may be respectively made of layers. The via 50 and the second conductive pattern 60 may be integrally formed through the same process and may not have boundaries with each other. For example, the via 50 and the second conductive pattern 60 may be integrally formed by forming a seed layer on a sidewall and a bottom of the via hole Vh and the photosensitive insulating layer 40, and forming a plating layer on the seed layer.

According to the present disclosure, it is possible to prevent the residues of the photosensitive insulating layer 40 from being formed on the first conductive pattern 20 and resulting in a defective electrical connection of the wire pattern by forming the protection pattern 31 on the first conductive pattern 20.

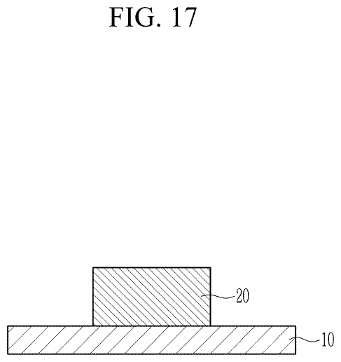

FIG. 17 to FIG. 23 show a method for manufacturing a wire structure according to an embodiment.

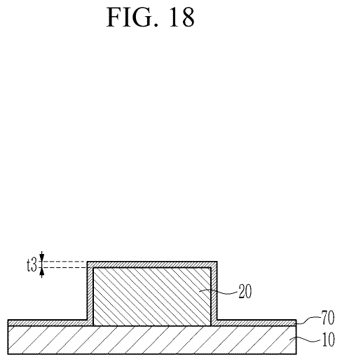

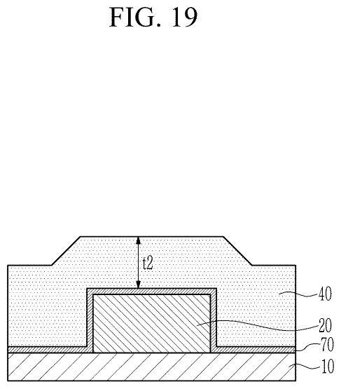

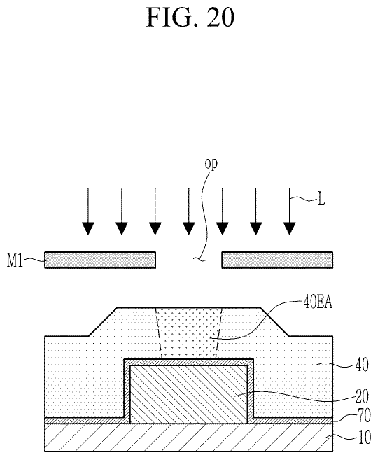

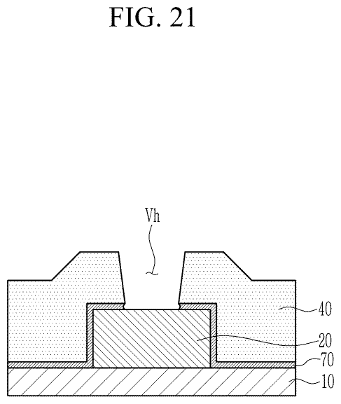

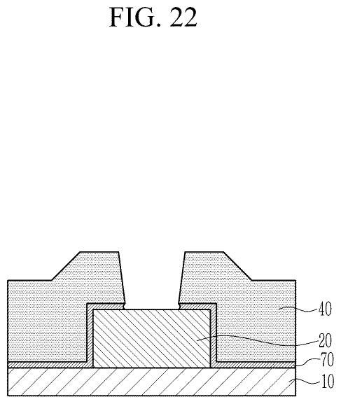

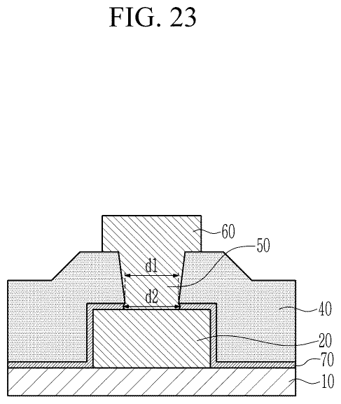

The method for manufacturing a wire structure may include: forming a first conductive pattern 20 on a substrate 10 (see FIG. 17); forming a passivation layer 70 for covering the first conductive pattern 20 (see FIG. 18); forming a photosensitive insulating layer 40 for covering the passivation layer 70 (see FIG. 19); patterning the photosensitive insulating layer 40 by an exposure process and a development process, removing a portion of the passivation layer 70, and forming a via hole Vh for exposing at least a portion of the first conductive pattern 20 (see FIGS. 20 and 21); curing the photosensitive insulating layer 40 (see FIG. 22); forming a via 50 for filling at least a portion of the via hole Vh and connected to the first conductive pattern 20 (see FIG. 23); and forming a second conductive pattern 60 connected to the via 50 on the via 50 (see FIG. 23).

Referring to FIG. 17, a first conductive pattern 20 may be formed on a substrate 10. The substrate 10 is not limited to specific types, and the substrate 10 may be a portion of the substrate or a semiconductor chip.

The first conductive pattern 20 may be a wire pattern (e.g., signal pattern, power pattern, or ground pattern) of the substrate, or a connection pad of the semiconductor chip. The first conductive pattern 20 may include a pad region overlapping the via 50 and connected thereto in a plan view.

The first conductive pattern 20 may be made of a conductive material, for example, copper (Cu), aluminum (Al), silver (Ag), gold (Au), platinum (Pt), nickel (Ni), titanium (Ti), palladium (Pd), or alloys thereof. The first conductive pattern 20 may be formed of layers. For example, the first conductive pattern 20 may be formed by forming a seed layer on the substrate 10, and forming a plating layer on the seed layer.

One first conductive pattern 20 is shown to be formed on the substrate 10 in the drawing, but multiple first conductive patterns 20 may also be formed.

Referring to FIG. 18, a passivation layer 70 for covering the first conductive pattern 20 may be formed. The passivation layer 70 may extend on the substrate 10 and may further cover the substrate 10 together with the first conductive pattern 20.

The passivation layer 70 may have non-photosensitivity. When light L is irradiated in the process for exposing the photosensitive insulating layer 40 to be described, it may be desirable for the passivation layer 70 to have non-photosensitivity to prevent the passivation layer 70 from being denatured and/or reacting to the first conductive pattern 20. The non-photosensitive passivation layer 70 may need no additional patterning, and may be continuously formed along an upper surface and a lateral surface of the first conductive pattern 20 and an upper surface of the substrate 10 to reduce the processing time and cost.

The passivation layer 70 may be formed to be thinner than the photosensitive insulating layer 40. For example, the thickness t3 (see FIG. 18) of the passivation layer 70 may be less than the thickness t2 (see FIG. 19) of the photosensitive insulating layer 40 on the passivation layer 70. The thickness t3 of the passivation layer 70 may represent the thickness of the passivation layer 70 at a region that is above an element covered by the passivation layer 70 in a vertical direction. As will be described, a portion of the passivation layer 70 may be removed in the subsequent process, and it may be preferable for the passivation layer 70 to be thin for the purpose of efficient removal of the passivation layer 70.

The passivation layer 70 may have heat resistance or may be thermally curable. The passivation layer 70 may preferably have heat resistance or may be thermally curable to prevent the passivation layer 70 from being input or diffused to the first conductive pattern 20 and polluting the same at the curing temperature in the process for curing the photosensitive insulating layer 40. The passivation layer 70 may, for example, be made of a thermally curable polyimide.

Referring to FIG. 19, a photosensitive insulating layer 40 for covering the passivation layer 70 may be formed. The photosensitive insulating layer 40 may be the photo imageable dielectric (PID). When the photosensitive insulating layer 40 is used, the photo vias may be formed, making it easy to implement fine pitches. The photosensitive insulating layer 40 may be formed through a lamination process, but is not limited thereto.

Referring to FIG. 20 and FIG. 21, the photosensitive insulating layer 40 may be patterned through the exposure process and the development process, and at least a portion of the passivation layer 70 may be removed to form a via hole Vh for exposing at least a portion of the first conductive pattern 20.

Referring to FIG. 20, the photomask M1 may be arranged on the photosensitive insulating layer 40, and the exposure process for irradiating light L on the photosensitive insulating layer 40 through photomask M1 may be performed. The photosensitive insulating layer 40 may be formed of a positive type material in which the region that is irradiated by light is thereafter removed by the development process. Therefore, the photomask M1 may have an open region op disposed in the region where the via hole Vh will be formed, and the light L may be irradiated to the region where the via hole Vh will be formed.

As described above, the passivation layer 70 may have non-photosensitivity. Therefore, when light L is irradiated through the photosensitive insulating layer 40 in the process for exposing the photosensitive insulating layer 40, the passivation layer 70 may be prevented from being denatured by the light L and/or reacting to the first conductive pattern 20.

Referring to FIG. 21, a via hole Vh may be formed by performing the development process for rinsing the photosensitive insulating layer 40 with a developer and removing the exposure region 40EA (see FIG. 20), and removing a portion of the passivation layer 70.

Regarding the passivation layer 70, the region overlapping the exposure region 40EA of the photosensitive insulating layer 40 may be removed, and the exposure region 40EA of the photosensitive insulating layer 40 may be connected to the removed region of the passivation layer 70 to thus form the via hole Vh.

The passivation layer 70 may be formed of a material that is developed by the developer of the photosensitive insulating layer 40. Therefore, a portion of the passivation layer 70 may be removed together with a portion of the photosensitive insulating layer 40 by the process for developing the photosensitive insulating layer 40. The processing time and cost may be reduced by removing the portions of the photosensitive insulating layer 40 and the passivation layer 70 by using the same developer.

However, if needed, the passivation layer 70 may be removed from the exposure region 40EA of the photosensitive insulating layer 40 by an additional process. For example, the photosensitive insulating layer 40 may be patterned by the exposure process and development process, and a portion of the passivation layer 70 may be separately removed to form the via hole Vh. The method for removing the passivation layer 70 is not limited, and the passivation layer 70 may be removed by a chemical method such as etching (wet etching, dry etching, plasma etching, etc.,) or a mechanical method depending on the material.

The shapes of the via hole Vh and the via 50 may become different according to etching forms when the via hole Vh is formed. For example, a portion of the passivation layer 70 may be removed in a direction facing a lateral portion of the passivation layer 70 in addition to a lower surface by isotropic etching. Therefore, the via 50 may include a region having a diameter d2 that is greater than a minimum diameter d1 of the via 50 in a region penetrating the passivation layer 70 and a region penetrating the photosensitive insulating layer 40 (see FIG. 23). For example, the region of the via 50 that has the diameter d2 may correspond to the former position of the passivation layer 70, while the region of the via 50 having the minimum diameter d1 may correspond to the former position of the bottom of the photosensitive insulating layer 40. For example, the diameter of the via 50 may narrow from top to bottom in the region corresponding to the former position of the photosensitive insulating layer 40, then may widen from top to bottom in an upper portion of the region of the via 50 corresponding to the former position of the passivation layer 70, and then may narrow from top to bottom in a lower portion of the region of the via 50 corresponding to the former position of the passivation layer 70.

The reactivity of the first conductive pattern 20 and the passivation layer 70 may be lower than the reactivity of the first conductive pattern 20 and the photosensitive insulating layer 40. Preferably, the first conductive pattern 20 and the passivation layer 70 may not react with each other. Therefore, no residue of the passivation layer 70 may remain on the first conductive pattern 20.

Referring to FIG. 22, the method for manufacturing a wire structure may further include curing the photosensitive insulating layer 40. The shape of the via hole Vh of the photosensitive insulating layer 40 may be maintained by curing the photosensitive insulating layer 40. The curing of the photosensitive insulating layer 40 may be performed at a specific temperature for a specific time.

Referring to FIG. 23, a via 50 filling at least a portion of the via hole Vh and connected to the first conductive pattern 20 may be formed, and a second conductive pattern 60 connected to the via 50 may be formed on the via 50.

The via 50 and the second conductive pattern 60 may be respectively made of conductive materials, for example, copper (Cu), aluminum (Al), silver (Ag), gold (Au), platinum (Pt), nickel (Ni), titanium (Ti), palladium (Pd), or their alloys. The via 50 and the second conductive pattern 60 may be respectively made of layers. The via 50 and the second conductive pattern 60 may be integrally formed by the same process and may not have boundaries with each other. For example, the via 50 and the second conductive pattern 60 may be integrally formed by forming a seed layer on the sidewall and the bottom of the via hole Vh and the photosensitive insulating layer 40, and forming a plating layer on the seed layer.

According to an embodiment, some regions of the passivation layer 70 may be removed, and other regions may remain when the via hole Vh is formed in the manufacturing process. Therefore, the wire structure formed according to an embodiment may include: a first conductive pattern 20, a passivation layer 70 covering the first conductive pattern 20, a photosensitive insulating layer 40 covering the passivation layer 70, and a via 50 connected to the first conductive pattern 20, and a second conductive pattern 60 disposed on the via 50 and connected to the via 50, and the via 50 may penetrate the passivation layer 70 and the photosensitive insulating layer 40 and may be connected to the first conductive pattern 20.

According to the present disclosure, it may be possible to prevent the formation of the residues of the photosensitive insulating layer 40 on the first conductive pattern 20 and the generation of electrical connection defects of the wire pattern by forming the passivation layer 70 on the first conductive pattern 20

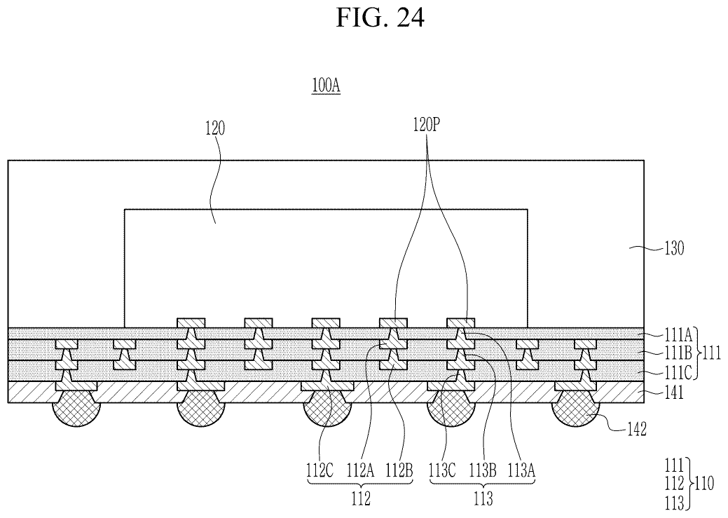

FIG. 24 shows a cross-sectional view of a semiconductor package including a wire structure according to an embodiment.

Referring to the drawings, the semiconductor package 100A may include a wire structure 110, a semiconductor chip 120, a molding material 130, a passivation film 141, and a first conductive bump 142.

The wire structure 110 may include photosensitive insulating layers 111, wiring layers 112 and vias 113. For example, the wire structure 110 may include a first photosensitive insulating layer 111A, first vias 113A penetrating the first photosensitive insulating layer 111A, a first wiring layer 112A disposed on the first photosensitive insulating layer 111A, a second photosensitive insulating layer 111B for covering the first wiring layer 112A, a second wiring layer 112B disposed on the second photosensitive insulating layer 111B, second vias 113B penetrating the second photosensitive insulating layer 111B and connecting the first wiring layer 112A to the second wiring layer 112B, a third photosensitive insulating layer 111C for covering the second wiring layer 112B, a third wiring layer 112C disposed on the third photosensitive insulating layer 111C, and third vias 113C penetrating the third photosensitive insulating layer 111C and connecting the second wiring layer 112B to the third wiring layer 112C.

The wiring layers 112 may include conductive pattern(s) for performing a function of the wire pattern. At this time, the wire structure 110 may be manufactured by the method shown in FIG. 8 to FIG. 16 for providing the protection pattern 31 on the conductive pattern.

For example, a region disposed between the first wiring layer 112A and the second wiring layer 112B of the wire structure 110 may be manufactured by forming a first wiring layer 112A including a conductive pattern, forming a protection pattern 31 on the conductive pattern of the first wiring layer 112A, forming a second photosensitive insulating layer 111B for covering the first wiring layer 112A and the protection pattern 31, patterning the second photosensitive insulating layer 111B and removing the protection pattern 31 to form a via hole for exposing a portion of the conductive pattern included in the first wiring layer 112A, forming a second via 113B filling the via hole and connected to the conductive pattern of the first wiring layer 112A, and forming a second wiring layer 112B including a conductive pattern connected to the second via 113B.

A region between a connection pad 120P of the semiconductor chip 120 and the first wiring layer 112A of the wire structure 110 may be manufactured by the same method, for example, by forming a protection pattern 31 on a connection pad 120P of the semiconductor chip 120, forming a first photosensitive insulating layer 111A for covering the connection pad 120P and the protection pattern 31, patterning the first photosensitive insulating layer 111A and removing the protection pattern 31 to form a via hole for exposing a portion of the connection pad 120P, forming a first via 113A filling the via hole and connected to the connection pad 120P, and forming a first wiring layer 112A including a conductive pattern connected to the first via 113A.

The semiconductor chip 120 may be arranged in a face-down form on the wire structure 110 so that the connection pad 120P may face the wire structure 110. At this time, the semiconductor chip 120 may be directly connected to the wire structure 110 without a separate connection member such as a conductive bump by applying a chip first process.

The molding material 130 may mold the semiconductor chip 120 to protect the semiconductor chip 120 from physical, mechanical, and chemical damages. The material of the molding material 130 may be an epoxy mold compound (EMC), but is not limited thereto.

The passivation film 141 may include an opening for covering a lower surface of the wire structure 110 and exposing a portion of the third wiring layer 112C disposed on the lowermost side. Solder resist may be used as a material for the passivation film 141, but is not limited thereto.

The first conductive bump 142 may electrically connect the semiconductor package 100A to other configurations such as a main board. The first conductive bump 142 may be electrically connected to the region exposed through the passivation film 141 of the third wiring layer 112C, and may be electrically connected to the wire structure 110 and the semiconductor chip 120. The first conductive bump 142 may, for example, be a solder bump.

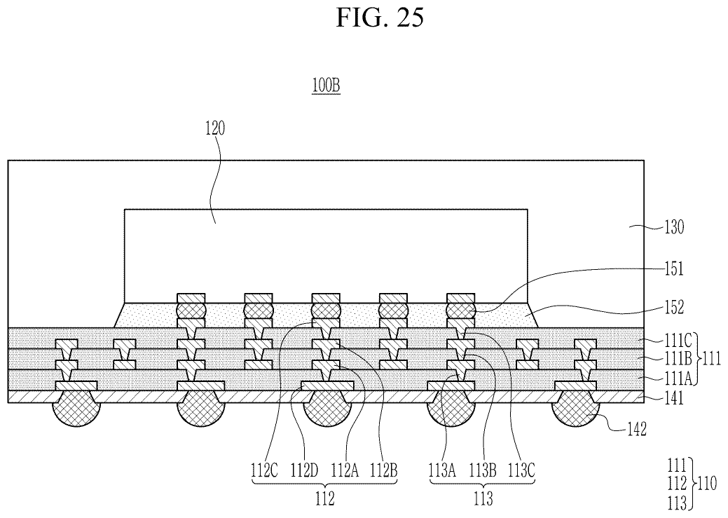

FIG. 25 shows a cross-sectional view on a semiconductor package including a wire structure formed according to an embodiment.

The semiconductor package 100B may further include a second conductive bump 151 and an underfill resin 152 in addition to the wire structure 110, the semiconductor chip 120, the molding material 130, the passivation film 141, and the first conductive bump 142.

Compared to the semiconductor package 100A, regarding the semiconductor package 100B, the wire structure 110 may further include a fourth wiring layer 112D embedded in the first photosensitive insulating layer 111A, and the first via 113A may connect the first wiring layer 112A to the fourth wiring layer 112D. In addition, the semiconductor chip 120 may be disposed on the third wiring layer 112C and may be connected to the wire structure 110 through the second conductive bump 151. The semiconductor chip 120 may be mounted on the wire structure 110 through the second conductive bump 151 by applying a chip last process.

The wire structure 110 of the semiconductor package 100B may be manufactured by the method for providing the protection pattern 31 on the conductive pattern shown in FIG. 8 to FIG. 16.

The passivation film 141 of the semiconductor package 100B may have an opening for covering the lower surface of the wire structure 110 and exposing a portion of the fourth wiring layer 112D disposed on the lowermost side. The first conductive bump 142 may be electrically connected to the exposed region through the passivation film 141 of the fourth wiring layer 112D, and may be electrically connected to the wire structure 110 and the semiconductor chip 120.

The contents given above in the description of the semiconductor package 100A may be applied to the description on other elements of the semiconductor package 100B.

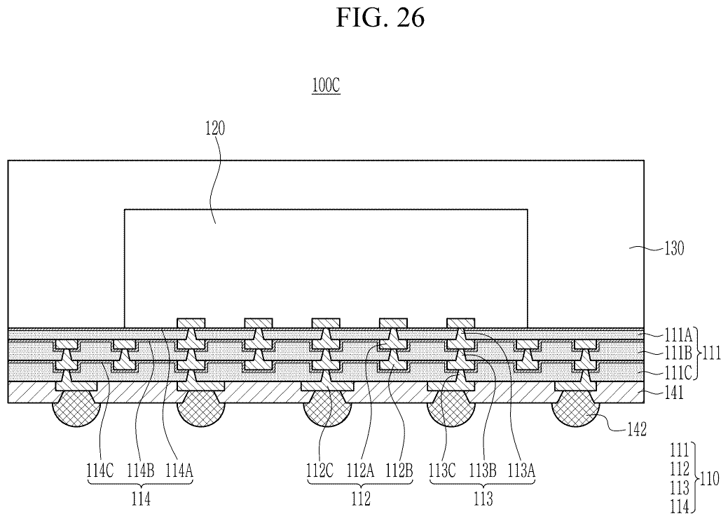

FIG. 26 shows a cross-sectional view of a semiconductor package including a wire structure formed according to an embodiment.

Compared to the semiconductor package 100A, the wire structure 110 of the semiconductor package 100C may be manufactured using the method for providing the passivation layer 114 on the conductive pattern shown in FIG. 17 to FIG. 23, and may further include the passivation layers 114.

The passivation layers 114 may include a first passivation layer 114A for covering the connection pad 120P of the semiconductor chip 120, a second passivation layer 114B for covering the first photosensitive insulating layer 111A and the first wiring layer 112A, and a third passivation layer 114C for covering the second wiring layer 112B and the second photosensitive insulating layer 111B.

For example, the region disposed between the first wiring layer 112A and the second wiring layer 112B of the wire structure 110 may be manufactured by forming a first wiring layer 112A including a conductive pattern, forming a second passivation layer 114B for covering the first wiring layer 112A, forming a second photosensitive insulating layer 111B for covering the second passivation layer 114B, patterning the second photosensitive insulating layer 111B and removing a portion of the second passivation layer 114B to form a via hole for exposing a portion of the conductive pattern included in the first wiring layer 112A, forming a second via 113B filling the via hole and connected to the conductive pattern of the first wiring layer 112A, and forming a second wiring layer 112B including a conductive pattern connected to the second via 113B.

The region disposed between the connection pad 120P of the semiconductor chip 120 and the first wiring layer 112A of the wire structure 110 may be manufactured by the same method, for example, by forming a first passivation layer 114A for covering the connection pad 120P of the semiconductor chip 120, forming a first photosensitive insulating layer 111A for covering the first passivation layer 114A, patterning the first photosensitive insulating layer 111A and removing a portion of the first passivation layer 114A to form a via hole for exposing a portion of the connection pad 120P, forming a first via 113A filling the via hole and connected to the connection pad 120P, and forming a first wiring layer 112A including a conductive pattern connected to the first via 113A.

The contents given above in the description of the semiconductor package 100A may be applied to the description of other elements of the semiconductor package 100C.

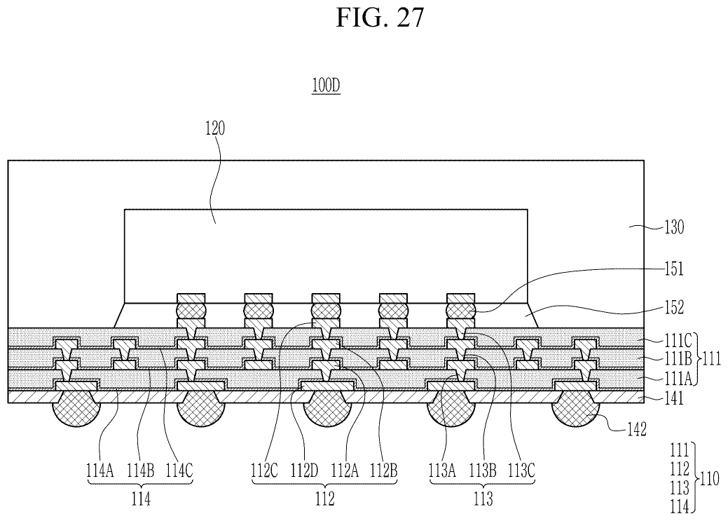

FIG. 27 shows a cross-sectional view of a semiconductor package including a wire structure formed according to an embodiment.

The semiconductor package 100D may further include a second conductive bump 151 and an underfill resin 152 in addition to the wire structure 110, the semiconductor chip 120, the molding material 130, the passivation film 141, and the first conductive bump 142.

Compared to the semiconductor package 100C, regarding the semiconductor package 100D, the wire structure 110 may further include a fourth wiring layer 112D embedded in the first photosensitive insulating layer 111A, and the first via 113A may connect the first wiring layer 112A to the fourth wiring layer 112D. The first passivation layer 114A of the wire structure 110 may be embedded in the first photosensitive insulating layer 111A and may cover the fourth wiring layer 112D. The semiconductor chip 120 may be disposed on the third wiring layer 112C and may be connected to the wire structure 110 through the second conductive bump 151. The semiconductor chip 120 may be mounted on the wire structure 110 through the second conductive bump 151 by applying the chip last process.

The wire structure 110 of the semiconductor package 100D may be manufactured by the method for providing the passivation layer 114 shown in FIG. 17 to FIG. 23.

The passivation film 141 of the semiconductor package 100D may have an opening for covering the lower surface of the wire structure 110 and exposing a portion of the fourth wiring layer 112D disposed on the lowermost side. The first conductive bump 142 may be electrically connected to the region exposed through the passivation film 141 of the fourth wiring layer 112D, and may be electrically connected to the wire structure 110 and the semiconductor chip 120.

The contents given above in the description of the semiconductor packages 100A and 100C may be applied to the description of other elements of the semiconductor package 100D.

Although the embodiment of the present disclosure has been described in detail, the scope of the present disclosure is not limited by the embodiment. Various changes and modifications using the basic concept of the present invention by those skilled in the art shall be construed to belong to the scope of the present disclosure.

Additionally, the embodiments of the present disclosure are not independent of each other and may be practiced in combination with each other unless specifically contradictory. Therefore, the embodiments that combine embodiments of the present disclosure should also be considered included in the present disclosure.

What is claimed is:

1. A method for manufacturing a wire structure, the method comprising:
forming a first conductive pattern on a substrate;
forming a protection pattern on the first conductive pattern;
forming a photosensitive insulating layer covering the first conductive pattern and the protection pattern;
patterning the photosensitive insulating layer by an exposure process and a development process, removing at least a portion of the protection pattern, and forming a via hole in the photosensitive insulating layer and the protection pattern, the via hole exposing at least a portion of the first conductive pattern;
forming a via filling at least a portion of the via hole and connected to the first conductive pattern; and
forming a second conductive pattern connected to the via on the via.

2. The method of claim 1, wherein
the protection pattern includes a photoresist material.

3. The method of claim 2, wherein
in the forming of the via hole, the protection pattern is removed with a portion of the photosensitive insulating layer by the exposure process and the development process of the photosensitive insulating layer.

4. The method of claim 3, wherein
the protection pattern and the photosensitive insulating layer are formed of a positive type material in which a region that is irradiated by light is thereafter removed by the development process, and
an entire region of the protection pattern overlaps, in a vertical direction, an open region of a photomask used in the exposure process.

5. The method of claim 2, wherein
the forming of the protection pattern includes:
forming a photoresist layer covering the first conductive pattern, and
patterning the photoresist layer by a second exposure process and a second development process to form the protection pattern.

6. The method of claim 2, wherein
a photosensitivity of the protection pattern is greater than a photosensitivity of the photosensitive insulating layer.

7. The method of claim 1, wherein
in the forming of the protection pattern, the protection pattern is formed to be thinner than the photosensitive insulating layer.

8. The method of claim 1, wherein
in the forming of the protection pattern, the protection pattern is formed to be narrower than the first conductive pattern in a cross-sectional view.

9. The method of claim 1, further comprising
curing the photosensitive insulating layer.

10. The method of claim 8, wherein
in the forming of the via hole, the entire protection pattern is removed.

11. A method for manufacturing a wire structure, the method comprising:
forming a first conductive pattern on a substrate;
forming a passivation layer covering the first conductive pattern;
forming a photosensitive insulating layer covering the passivation layer;
patterning the photosensitive insulating layer by an exposure process and a development process, removing a portion of the passivation layer, and forming a via hole in the photosensitive insulating layer and the passivation layer, the via hole exposing at least a portion of the first conductive pattern;
forming a via filling at least a portion of the via hole and connected to the first conductive pattern; and
forming a second conductive pattern connected to the via on the via.

12. The method of claim 11, wherein
the passivation layer has non-photosensitivity.

13. The method of claim 12, wherein
the portion of the passivation layer is removed with a portion of the photosensitive insulating layer by the development process of the photosensitive insulating layer.

14. The method of claim 11, wherein
in the forming of the passivation layer, the passivation layer is formed to be thinner than the photosensitive insulating layer.

15. The method of claim 11, wherein
in the forming of the passivation layer, the passivation layer is formed to extend on the substrate and further cover the substrate.

16. The method of claim 11, further comprising
curing the photosensitive insulating layer.

17. A wire structure comprising:
a first conductive pattern;
a passivation layer covering the first conductive pattern;
a photosensitive insulating layer covering the passivation layer;
a via penetrating the passivation layer and the photosensitive insulating layer, the via being connected to the first conductive pattern; and
a second conductive pattern disposed on the via and connected to the via.

18. The wire structure of claim 17, wherein
the passivation layer has non-photosensitivity.

19. The wire structure of claim 17, wherein
the passivation layer is thinner than the photosensitive insulating layer.

20. The wire structure of claim 17, wherein
the via includes a first region penetrating the passivation layer having a first diameter and a second region penetrating the photosensitive insulating layer having a minimum diameter, and
the first diameter of the first region is greater than the minimum diameter of the second region.
